(19) United States
(12) Patent Application Publication
(10) Pub. No.: US 2025/0054549 A1
(43) Pub. Date: Feb. 13, 2025

(54) PARTIALLY PROGRAMMED BLOCK PADDING OPERATIONS

(71) Applicant: Micron Technology, Inc., Boise, ID (US)

(72) Inventors: Nagendra Prasad Ganesh Rao, Folsom, CA (US); Paing Htet, Union City, CA (US); Zhenming Zhou, San Jose, CA (US)

(21) Appl. No.: 18/756,573

(22) Filed: Jun. 27, 2024

Related U.S. Application Data
(60) Provisional application No. 63/531,091, filed on Aug. 7, 2023.

(51) Int. Cl. G11C 16/10; G11C 16/08; G11C 16/26

(52) U.S. Cl. CPC G11C 16/102; G11C 16/08; G11C 16/26

(57) ABSTRACT

Apparatuses and methods for programming partially programmed blocks with padding are provided. One example apparatus can include a controller configured to program a first number of word lines in a block of word lines in the array of memory cells, wherein the first number of word lines is less that a total number of word lines in the block, and program a second number of word lines of the array of memory cells, wherein the second number of word lines are programmed with padding and wherein the second number of word lines are different word lines that the first number of word lines and the total number of word lines in the block includes the first and second number of word lines.

### CROSS-REFERENCE TO RELATED APPLICATION

This application claims the benefit of U.S. Provisional Application No. 63/531,091, filed on Aug. 7, 2023, the contents of which are incorporated herein by reference.

### TECHNICAL FIELD

The present disclosure relates generally to partially programmed blocks, and more particularly, to apparatuses and methods for programming partially programmed blocks with padding.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, phase change random access memory (PCRAM), resistive random access memory (RRAM), and magnetic random access memory (MRAM), among others.

Memory devices can be combined together to form a solid state drive (SSD). An SSD can include non-volatile memory, e.g., NAND flash memory and/or NOR flash memory, and/or can include volatile memory, e.g., DRAM and/or SRAM, among various other types of non-volatile and volatile memory. Flash memory devices can include memory cells storing data in a charge storage structure such as a floating gate, for instance, and may be utilized as non-volatile memory for a wide range of electronic applications. Flash memory devices typically use a one-transistor memory cell that allows for high memory densities, high reliability, and low power consumption.

An SSD can be used to replace hard disk drives as the main storage volume for a computer, as the solid state drive can have advantages over hard drives in terms of performance, size, weight, ruggedness, operating temperature range, and power consumption. For example, SSDs can have superior performance when compared to magnetic disk drives due to their lack of moving parts, which may avoid seek time, latency, and other electro-mechanical delays associated with magnetic disk drives.

Memory is utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

Memory cells in an array architecture can be programmed to a desired state. For instance, electric charge can be placed on or removed from the charge storage structure, e.g., floating gate, of a memory cell to program the cell to a particular state. For example, a single level (memory) cell (SLC) can be programmed to one of two different states, each representing a different digit of a data value, e.g., a 1 or 0. Some flash memory cells can be programmed to one of more than two states corresponding to different particular data values, e.g., 1111, 0111, 0011, 1011, 1001, 0001, 0101, 1101, 1100, 0100, 0000, 1000, 1010, 0010, 0110, or 1110. Such cells may be referred to as multi state memory cells, multiunit cells, or multilevel (memory) cells (MLCs). MLCs can provide higher density memories without increasing the number of memory cells since each cell can be programmed to states corresponding to more than one digit, e.g., more than one bit of data.

### BRIEF DESCRIPTION OF THE DRAWINGS

FIG. 1 is a block diagram of an apparatus in the form of a computing system including at least one memory system in accordance with a number of embodiments of the present disclosure.

FIG. 2 illustrates a schematic diagram of a portion of a non-volatile memory array in accordance with a number of embodiments of the present disclosure.

FIG. 3A illustrates a table indicating data stored in word lines when padding a partially programmed block in accordance with an embodiment of the present disclosure.

FIG. 3B illustrates a table indicating data stored in word lines when padding a partially programmed block in accordance with an embodiment of the present disclosure.

FIG. 4 is a flow diagram a method for operating a controller configured to pad a partially programmed block in accordance with a number of embodiments of the present disclosure.

### DETAILED DESCRIPTION

The present disclosure provides apparatuses and methods for programming partially programmed blocks with padding are provided. One example apparatus can include a controller configured to program a first number of word lines in a block of word lines in the array of memory cells, wherein the first number of word lines is less that a total number of word lines in the block, and program a second number of word lines of the array of memory cells, wherein the second number of word lines are programmed with padding and wherein the second number of word lines are different word lines that the first number of word lines and the total number of word lines in the block includes the first and second number of word lines.

When a memory device is being programmed, a read command may be received for data that is located in a partially programmed block (e.g., a block where a portion of the word lines are programmed, and a portion of the word lines are unprogrammed in an erased state). During a read operation, the threshold voltage for memory cells in a partially programmed block can be different than the threshold voltage of memory cells in a fully programmed block due to the back pattern effect. When the same pass voltage is applied to the word lines that are not being sensed in a partially programmed block and in a fully programmed block, the word lines being sensed in a partially programmed block can have a lower threshold voltage than word lines being sensed in a fully programmed block due to a partially programmed block experiencing a different string current than a fully programmed block.

In a number of embodiments, lower threshold voltages in partially programmed blocks can also be attributed to capacitive coupling between programmed word lines and unprogrammed word lines and to lateral charge migration between programmed word lines and unprogrammed word lines.

In a number of embodiments, when a programming operation on a partially programmed block is completed or interrupted, the remaining unprogrammed word lines in the partially programmed block can be programmed with padding. The padding can be random invalid data received from a host and/or generated by a controller on a memory device. The padding can program the previously unprogrammed word lines in the partially programmed block with data that can reduce the reduction in threshold voltages when reading data in the partially programmed block caused by the back pattern effect, capacitive coupling, and/or lateral charge migration.

In a number of embodiments, padding can be programmed using a course programming operation in a quad level cell (QLC) mode, which can be the same mode that was used to program the valid data in the partially programmed block. Padding can also be programmed using a programming operation in a single level cell (SLC) mode, multilevel cell (MLC) mode, and/or a triple level cell (TLC) mode, where the mode is changed from the mode that was used to program the valid data in the partially programmed block. Programming the padding with a course QPL programming operation and/or a programming operation in SLC, MLC, or TLC mode can allow the padding to occur in less time that continuing to program the block with padding using a normal QLC programming operation that includes both a course and fine programming operations. Programming the padding using a course QLC programming operation can reduce the padding programming time by more than 70% when compared to padding using a normal QLC programming operation that includes both a course and fine programming operations. Programming the padding using a TLC programming operation can reduce the padding programming time by more than 80% when compared to padding using a normal QLC programming operation that includes both a course and fine programming operations. The programming time for programming the padding using a SLC programming operation can be 10 times faster than padding using a normal QLC programming operation that includes both a course and fine programming operations.

In the following detailed description of the present disclosure, reference is made to the accompanying drawings that form a part hereof, and in which is shown by way of illustration how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

As used herein, “a number of” something can refer to one or more such things. For example, a number of memory cells can refer to one or more memory cells. Additionally, the designators “M” and “N” as used herein, particularly with respect to reference numerals in the drawings, indicates that a number of the particular feature so designated can be included with a number of embodiments of the present disclosure.

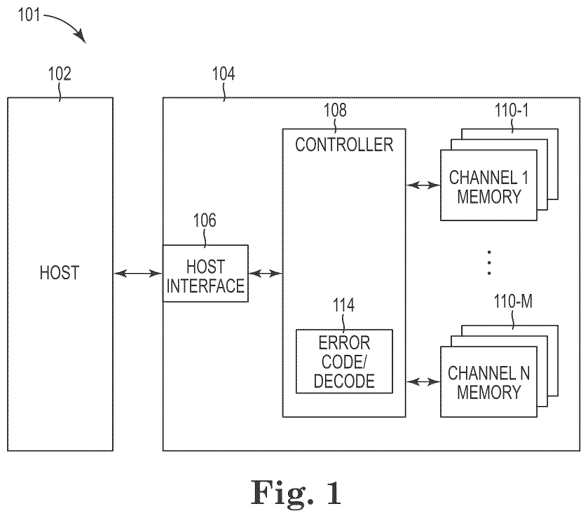

The figures herein follow a numbering convention in which the first bit or bits correspond to the drawing figure number and the remaining bits identify an element or component in the drawing. Similar elements or components between different figures may be identified by the use of similar bits. For example, 100 may reference element “00” in FIG. 1, and a similar element may be referenced as 600 in FIG. 6. Elements shown in the various embodiments herein can be added, exchanged, and/or eliminated so as to provide a number of additional embodiments of the present disclosure. In addition, the proportion and the relative scale of the elements provided in the figures are intended to illustrate the embodiments of the present disclosure, and should not be taken in a limiting sense.

FIG. 1 is a block diagram of an apparatus in the form of a computing system 101 including at least one memory system 104 in accordance with a number of embodiments of the present disclosure. As used herein, a memory system 104, a controller 108, or a memory device 110 might also be separately considered an “apparatus”. The memory system 104 can be a solid state drive (SSD), for instance, and can include a host interface 106, a controller 108, e.g., a processor and/or other control circuitry, and a number of memory devices 110-1, . . . , 510-M, e.g., solid state memory devices such as NAND flash devices, which provide a storage volume for the memory system 104. In a number of embodiments, the controller 108, a memory device 110-1 to 110-M, and/or the host interface 106 can be physically located on a single die or within a single package, e.g., a managed NAND application. Also, in a number of embodiments, a memory, e.g., memory devices 110-1 to 110-M, can include a single memory device.

As illustrated in FIG. 1, the controller 108 can be coupled to the host interface 106 and to the memory devices 110-1, . . . , 110-M via a plurality of channels and can be used to transfer data between the memory system 104 and a host 102. Interface 106 can be in the form of a standardized interface. For example, when the memory system 104 is used for data storage in a computing system 100, the interface 106 can be a serial advanced technology attachment (SATA), peripheral component interconnect express (PCIe), or a universal serial bus (USB), among other connectors and interfaces. In general, however, interface 106 can provide an interface for passing control, address, data, and other signals between the memory system 104 and a host 102 having compatible receptors for the interface 106.

Host 102 can be a host system such as a personal laptop computer, a desktop computer, a digital camera, a mobile telephone, or a memory card reader, among various other types of hosts. Host 102 can include a system motherboard and/or backplane and can include a number of memory access devices, e.g., a number of processors.

The controller 108 can communicate with the memory devices 110-1, . . . , 110-M to control data read, write, and erase operations, among other operations. The controller 108 can include, for example, a number of components in the form of hardware and/or firmware, e.g., one or more integrated circuits, and/or software for controlling access to the number of memory devices 110-1, . . . , 110-M and/or for facilitating data transfer between the host 102 and memory devices 110-1, 110-M. For instance, in the example illustrated in FIG. 1, controller 108 includes an error correcting code encoder/decoder component 114. However, controller 108 can include various other components not illustrated so as not to obscure embodiments of the present disclosure. Also, component 114 may not be components of controller 108, in some embodiments, e.g., component 114 can be independent components.

The error correcting code encoder/decoder component 114 can be an LDPC encoder/decoder, for instance, which can encode/decoder user data transferred between host 102 and the memory devices 110-1, . . . , 110-M.

The memory devices 110-1, . . . , 110-M can include a number of arrays of memory cells. The arrays can be flash arrays with a NAND architecture, for example. However, embodiments are not limited to a particular type of memory array or array architecture. The memory cells can be grouped, for instance, into a number of blocks including a number of physical pages. A number of blocks can be included in a plane of memory cells and an array can include a number of planes. As one example, a memory device may be configured to store 8 KB (kilobytes) of user data per page, 128 pages of user data per block, 2048 blocks per plane, and 16 planes per device.

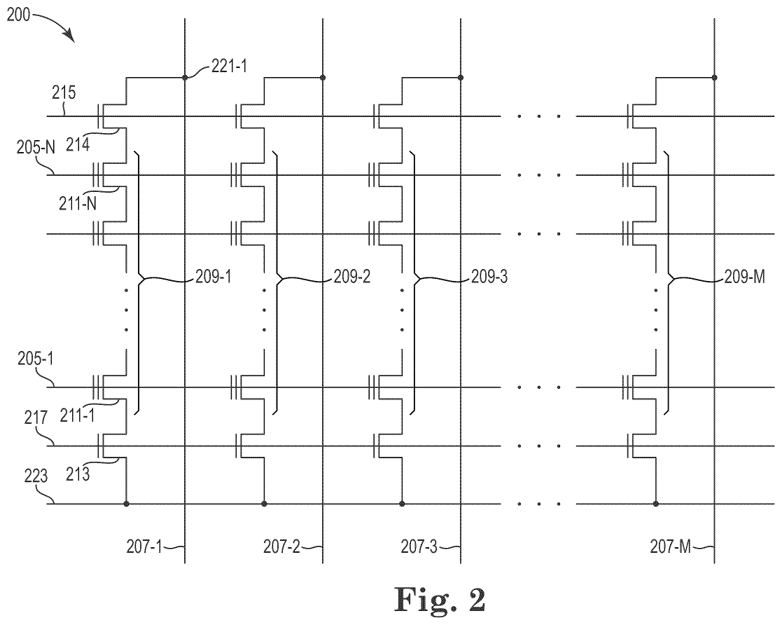

FIG. 2 illustrates a schematic diagram of a portion of a non-volatile memory array 200 in accordance with a number of embodiments of the present disclosure. The embodiment of FIG. 2 illustrates a NAND architecture non-volatile memory array, e.g., NAND Flash. However, embodiments described herein are not limited to this example. As shown in FIG. 2, memory array 200 includes access lines, e.g., word lines 205-1, . . . , 205-N, and intersecting data lines, e.g., local bit lines, 207-1, 207-2, 207-3, . . . , 207-M. For ease of addressing in the digital environment, the number of word lines 205-1, . . . , 205-N and the number of local bit lines 207-1, 207-2, 207-3, . . . , 207-M can be some power of two, e.g., 256 word lines by 4,096 bit lines.

Memory array 200 includes NAND strings 209-1, 209-2, 209-3, . . . , 209-M. Each NAND string includes non-volatile memory cells 211-1, . . . , 211-N, each communicatively coupled to a respective word line 205-1, . . . , 205-N. Each NAND string (and its constituent memory cells) is also associated with a local bit line 207-1, 207-2, 207-3, . . . , 207-M. The non-volatile memory cells 211-1, . . . , 211-N of each NAND string 209-1, 209-2, 209-3, . . . , 209-M are connected in series source to drain between a source select gate (SGS), e.g., a field-effect transistor (FET), 213, and a drain select gate (SGD), e.g., FET, 214. Each source select gate 213 is configured to selectively couple a respective NAND string to a common source 223 responsive to a signal on source select line 217, while each drain select gate 214 is configured to selectively couple a respective NAND string to a respective bit line responsive to a signal on drain select line 215.

As shown in the embodiment illustrated in FIG. 2, a source of source select gate 213 is connected to a common source line 223. The drain of source select gate 213 is connected to the source of the memory cell 211-1 of the corresponding NAND string 209-1. The drain of drain select gate 214 is connected to bit line 207-1 of the corresponding NAND string 209-1 at drain contact 221-1. The source of drain select gate 214 is connected to the drain of the last memory cell 211-N, e.g., a floating-gate transistor, of the corresponding NAND string 209-1.

In a number of embodiments, construction of non-volatile memory cells 211-1, . . . , 211-N includes a source, a drain, a charge storage structure such as a floating gate, and a control gate. Non-volatile memory cells 211-1, . . . , 211-N have their control gates coupled to a word line, 205-1, . . . , 205-N, respectively. A “column” of the non-volatile memory cells, 211-1, . . . , 211-N, make up the NAND strings 209-1, 209-2, 209-3, . . . , 209-M, and are coupled to a given local bit line 207-1, 207-2, 207-3, . . . , 207-M, respectively. A “row” of the non-volatile memory cells are those memory cells commonly coupled to a given word line 205-1, . . . , 205-N. The use of the terms “column” and “row” is not meant to imply a particular linear, e.g., vertical and/or horizontal, orientation of the non-volatile memory cells. A NOR array architecture would be similarly laid out, except that the string of memory cells would be coupled in parallel between the select gates.

Subsets of cells coupled to a selected word line, e.g., 205-1, . . . , 205-N, can be programmed and/or read together as a page of memory cells. A programming operation, e.g., a write operation, can include applying a number of program pulses, e.g., 16V-20V, to a selected word line in order to increase the threshold voltage (Vt) of selected cells coupled to that selected access line to a desired program voltage level corresponding to a target, e.g., desired, state, e.g., charge storage state. State is equivalently referred to as “level” herein.

A read operation, which can also refer to a program verify operation, can include sensing a voltage and/or current change of a bit line coupled to a selected cell in order to determine the state of the selected cell. The states of a particular fractional bit memory cell may not correspond directly to a data value of the particular memory cell, rather the states of a group of memory cells including the particular memory cell together map to a data value having an integer number of bits. The read operation can include pre-charging a bit line and detecting the discharge when a selected cell begins to conduct.

Determining, e.g., detecting, the state of a selected cell can include providing a number of sensing signals, e.g., read voltages, to a selected word line while providing a number of voltages, e.g., read pass voltages, to the word lines coupled to the unselected cells of the string sufficient to place the unselected cells in a conducting state independent of the threshold voltage of the unselected cells. The bit line corresponding to the selected cell being read and/or verified can be detected to determine whether or not the selected cell conducts in response to the particular sensing signal applied to the selected word line. For example, the state of a selected cell can be determined by the word line voltage at which the bit line current reaches a particular reference current associated with a particular state.

The array can comprise single level cells (SLCs) storing 1 bit per cell, multilevel cells (MLCs) storing 2 bits per cell, triple level cells (TLCs) storing three bits per cell, or quad level cells (QLCs) storing 4 bits per cell, for example. Embodiments are not limited to a particular type of memory cell.

MLCs can be two-bit, e.g., four-state, memory cells, or can store more than two bits of data per memory cell, including fractional bits of data per memory cell. For example, a two-bit memory cell can be programmed to one of four states, e.g., P0, P1, P2, and P3, respectively. In operation, a number of memory cells, such as in a selected block, can be programmed such that they have a Vt level corresponding to either P0, P1, P2, or P3. As an example, state P0 can represent a stored data value such as binary “11”. State P1 can represent a stored data value such as binary “10”. State P2 can represent a stored data value such as binary “00”. State P3 can represent a stored data value such as binary “01”. However, embodiments are not limited to these data value correspondence.

TLCs can be three-bit, e.g., eight-state, memory cells, or can store more than three bits of data per memory cell, including fractional bits of data per memory cell. For example, a three-bit memory cell can be programmed to one of eight states, e.g., P0, P1, P2, P3, P4, P5, P6, or P7, respectively. In operation, a number of memory cells, such as in a selected block, can be programmed such that they have a Vt level corresponding to either P0, P1, P2, P3, P4, P5, P6, or P7. As an example, state P0 can represent a stored data value such as binary “111”. State P1 can represent a stored data value such as binary “110”. State P2 can represent a stored data value such as binary “101”. State P3 can represent a stored data value such as binary “100”. State P4 can represent a stored data value such as binary “011”. State P5 can represent a stored data value such as binary “010”. State P6 can represent a stored data value such as binary “001”. State P7 can represent a stored data value such as binary “000”. However, embodiments are not limited to these data value correspondence.

QLCs can be four-bit, e.g., sixteen-state, memory cells, or can store more than four bits of data per memory cell, including fractional bits of data per memory cell. For example, a four-bit memory cell can be programmed to one of sixteen states, e.g., P0, P1, P2, P3, P4, P5, P6, P7, P8, P9, P10, P11, P12, P13, P14, or P15, respectively. In operation, a number of memory cells, such as in a selected block, can be programmed such that they have a Vt level corresponding to either P0, P1, P2, P3, P4, P5, P6, or P7. As an example, state P0 can represent a stored data value such as binary “1111”. State P1 can represent a stored data value such as binary “1100”. State P2 can represent a stored data value such as binary “1101”. State P3 can represent a stored data value such as binary “1100”. State P4 can represent a stored data value such as binary “1011”. State P5 can represent a stored data value such as binary “1010”. State P6 can represent a stored data value such as binary “1001”. State P7 can represent a stored data value such as binary “1000”. State P8 can represent a stored data value such as binary “0111”. State P9 can represent a stored data value such as binary “0110”. State P10 can represent a stored data value such as binary “0101”. State P11 can represent a stored data value such as binary “0100”. State P12 can represent a stored data value such as binary “0011”. State P13 can represent a stored data value such as binary “0010”. State P14 can represent a stored data value such as binary “0001”. State P15 can represent a stored data value such as binary “0000”. However, embodiments are not limited to these data value correspondence.

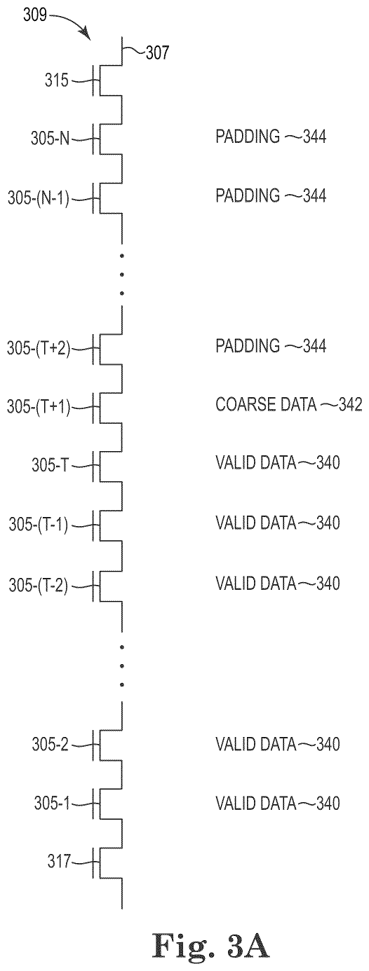

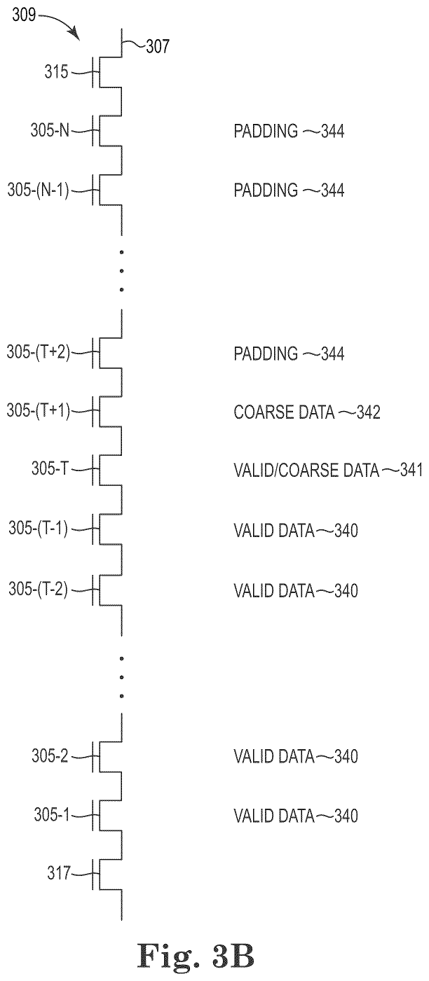

FIG. 3A illustrates a table indicating data stored in word lines when padding a partially programmed block in accordance with an embodiment of the present disclosure. The table illustrates the type of data programmed to a partially programmed block when padding the partially programmed block in accordance with an embodiment of the present disclosure. When performing a programming operation, the programming operation may end with a block not fully programmed resulting in a partially programmed block. Also, when performing a programming operation, the programming operation may be interrupted or stopped before it is completed resulting in a partially programmed block. When reading data on a partially programmed block, the threshold voltages of the memory cells may be lower than the threshold voltages of memory cells on a fully programmed block due to back pattern effect, capacitive coupling, and/or lateral charge migration. The memory cells on word lines that were not programmed due to the programming operation being completed or interrupted can be programmed with padding to reduce the drop in threshold voltage in memory cells due to back pattern effect, capacitive coupling, and/or lateral charge migration when reading memory cells on the partially programmed block.

As shown in FIG. 3A, a programming operation can begin by programming valid data 340 to the memory cells coupled to word line 305-1. The programming operation can continue to program valid data 340 to the memory cells coupled to word lines 305-2 to 304-(T−1). In FIG. 3A, once the programming operation reaches word line 305-T and programs valid data 340 to the memory cells coupled to word line 305-T, the programming operation can be complete, interrupted, or canceled resulting in a partially programmed block.

The memory cells that were not programmed during the programming operation can be programmed with padding to reduce drop in threshold voltage due to back pattern effect, capacitive coupling, and/or lateral charge migration when reading memory cells on the partially programmed block. Since the programming operation was completed, interrupted, or canceled when programming valid data 340 to the memory cells coupled to word line 305-T, the memory cells coupled to word line 305-(T+1) have been programmed with course data 342 as part of the QLC programming operation performed on word lines 305-1 to 305-T, therefore programming padding can begin on the memory cells coupled to word line 305-(T+2).

The memory cells coupled to word lines 305-(T+2) to 305-N can be programmed with padding 344. Padding 344 can be invalid random data. The random data can be received from a host coupled to the memory device and/or generated by the controller of the memory device. Padding 344 can be programmed using a course programming operation in QLC mode. Padding can also be performed using SLC, MLC, and/or TLC programming operations by switching from QLC mode to SLC, MLC, and/or TCL mode to perform the padding programming operation.

FIG. 3B illustrates a table indicating data stored in word lines when padding a partially programmed block in accordance with an embodiment of the present disclosure. The table illustrates the type of data programmed to a partially programmed block when padding the partially programmed block in accordance with an embodiment of the present disclosure. When performing a programming operation, the programming operation may end with a portion of word line of a block not fully programmed resulting in a partially programmed block. Also, when performing a programming operation, the programming operation may be interrupted or stopped before it is completed resulting in a portion of word line of a block not fully programmed resulting in a partially programmed block. In FIG. 3B, the memory cells coupled to word line 305-T are partially programmed, where a first portion of memory cells are programmed with valid data and a second portion of memory cells are programmed with course data (e.g., the programming operation on the second portion of memory cells is incomplete). When reading data on a partially programmed block, the threshold voltages of the memory cells may be lower than the threshold voltages of memory cells on a fully programmed block due to back pattern effect, capacitive coupling, and/or lateral charge migration. The memory cells on word lines that were not programmed due to the programming operation being completed or interrupted can be programmed with padding to reduce the drop in threshold voltage in memory cells due to back pattern effect, capacitive coupling, and/or lateral charge migration when reading memory cells on the partially programmed block.

As shown in FIG. 3B, a programming operation can begin by programming valid data 340 to the memory cells coupled to word line 305-1. The programming operation can continue to program valid data 340 to the memory cells coupled to word lines 305-2 to 304-(T−1). In FIG. 3B, once the programming operation reaches word line 305-T and programs valid data 340 to a first portion of the memory cells coupled to word line 305-T and course data 342 to a second portion of the memory cells coupled to word line 305-T, the programming operation can be complete, interrupted, or canceled resulting in a partially programmed block.

The memory cells that were not programmed during the programming operation can be programmed with padding to reduce drop in threshold voltage due to back pattern effect, capacitive coupling, and/or lateral charge migration when reading memory cells on the partially programmed block. Since the programming operation was completed, interrupted, or canceled when programming the memory cells coupled to word line 305-T, the second portion of the memory cells coupled to word line 305-T and the memory cells coupled to word line 305-(T+1) have been programmed with course data 342 as part of the QLC programming operation performed on word lines 305-1 to 305-T, therefore programming padding can begin on the memory cells coupled to word line 305-(T+2).

The memory cells coupled to word lines 305-(T+2) to 305-N can be programmed with padding 344. Padding 344 can be invalid random data. The random data can be received from a host coupled to the memory device and/or generated by the controller of the memory device. Padding 344 can be programmed using a course programming operation in QLC mode. Padding can also be performed using SLC, MLC, and/or TLC programming operations by switching from QLC mode to SLC, MLC, and/or TCL mode to performing the padding programming operation.

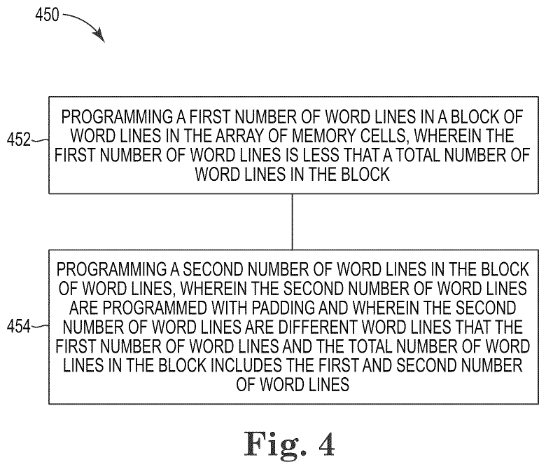

FIG. 4 is a flow diagram a method 450 for operating a controller configured to pad a partially programmed block in accordance with a number of embodiments of the present disclosure.

At 452, the method can include programming a first number of word lines in a block of word lines in the array of memory cells, wherein the first number of word lines is less than a total number of word lines in the block, as illustrated at 305-1 to 305-T in FIGS. 3A and 3B.

At 454, the method can include programming a second number of word lines in the block of word lines, wherein the second number of word lines are programmed with padding and wherein the second number of word lines are different word lines that the first number of word lines and the total number of word lines in the block includes the first and second number of word lines, as illustrated at 305-1 to 305-(T+2) to 305-N in FIGS. 3A and 3B.

The method can include programming the first number of word lines in a first mode and programming the second number of word lines in a second mode. Programming the second number of word lines with padding can include using a course programming operation in QLC mode, using a programming operation in SLC mode, using a programming operation in MLC mode, and/or using a programming operation in TLC mode.

The method can include performing a sensing operation on one of the first number of word lines in a partially programmed block in response to the second number of word lines being programmed. The sensing operation on the partially programmed block uses sensing voltages used in a sensing operation performed on a fully programmed block.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
an array of memory cells;
a controller coupled to the array of memory cells and the controller is configured to:
program a first number of word lines in a block of word lines in the array of memory cells, wherein the first number of word lines is less that a total number of word lines in the block; and
program a second number of word lines of the array of memory cells, wherein the second number of word lines are programmed with padding and wherein the second number of word lines are different word lines that the first number of word lines and the total number of word lines in the block includes the first and second number of word lines.

2. The apparatus of claim 1, wherein the first number of word lines are programmed with valid data and the second number of word lines are programmed with invalid data.

3. The apparatus of claim 1, wherein the block is a partially programmed block comprising the first number of word lines programmed with valid data and the second number of word lines programmed with invalid data.

4. The apparatus of claim 3, wherein the controller is configured to perform a sensing operation on one of the first number of word lines in the partially programmed block in response to the second number of word lines being programmed.

5. The apparatus of claim 1, wherein the controller is configured to program the first number of word lines using programming operations in a first mode and to program the second number of work lines using programming operations in a second mode.

6. The apparatus of claim 1, wherein the second number of word lines are programmed using a course programming operation in a quad level cell (QLC) mode.

7. The apparatus of claim 1, wherein the second number of word lines are programmed using a programming operation in a single level cell (SLC) mode.

8. The apparatus of claim 1, wherein the second number of word lines are programmed using a programming operation in a multilevel cell (MLC) mode.

9. An apparatus, comprising:
an array of memory cells;
a controller coupled to the array of memory cells and the controller is configured to:
program a first number of word lines in a block of word lines in the array of memory cells with valid data using a programming operation in quad level cell (QLC) mode, wherein the first number of word lines is less that a total number of word lines in the block; and
program a second number of word lines in the block of word lines in the array of memory cells with padding, wherein the second number of word lines were unprogrammed when programming the first number of word lines in the block.

10. The apparatus of claim 9, wherein the controller is configured to program the second number of word lines with padding using a course programming operation in QLC mode.

11. The apparatus of claim 9, wherein the controller is configured to switch modes prior to programming the second number of word lines.

12. The apparatus of claim 11, wherein the controller is configured to program the second number of word lines with padding using a programming operation in a single level cell (SLC) mode.

13. The apparatus of claim 11, wherein the controller is configured to program the second number of word lines with padding using a programming operation in a multilevel cell (MLC) mode.

14. The apparatus of claim 11, wherein the controller is configured to program the second number of word lines with padding using a programming operation a triple level cell (TLC) mode.

15. A method, comprising:
programming a first number of word lines in a block of word lines in the array of memory cells, wherein the first number of word lines is less that a total number of word lines in the block; and
programming a second number of word lines in the block of word lines, wherein the second number of word lines are programmed with padding and wherein the second number of word lines are different word lines that the first number of word lines and the total number of word lines in the block includes the first and second number of word lines.

16. The method of claim 15, furthering including programming the first number of word lines in a first mode and programming the second number of word lines in a second mode.

17. The method of claim 15, further including programming the second number of word lines using a course programming operation in quad level cell (QLC) mode.

18. The method of claim 15, further including programming the second number of word lines using a course programming operation in a single level cell (SLC) mode.

19. The method of claim 15, further including performing a sensing operation on one of the first number of word lines in a partially programmed block in response to the second number of word lines being programmed.

20. The method of claim 19, wherein the sensing operation on the partially programmed block uses sensing voltages used in a sensing operation performed on a fully programmed block.
